(19) United States
(12) Patent Application Publication
(10) Pub. No.: US 2011/0048775 A1
(43) Pub. Date: Mar. 3, 2011

(54) PRINTED WIRING BOARD AND METHOD FOR MANUFACTURING THE SAME

(75) Inventors: Atsushi ISHIDA, Ogaki-shi (JP); Ryojiro Tominaga, Ogaki-shi (JP); Kenji Sakai, Ogaki-shi (JP)

(73) Assignee: IBIDEN CO., LTD., Ogaki-shi (JP)

(21) Appl. No.: 12/857,838

(22) Filed: Aug. 17, 2010

Related U.S. Application Data
(60) Provisional application No. 61/238,468, filed on Aug. 31, 2009.

(51) Int. Cl. H05K 1/00; H05K 1/11; H05K 3/00

(52) U.S. Cl. 174/258; 174/262; 174/266; 29/829

(57) ABSTRACT

A printed wiring board includes a substrate having a first surface and a second surface on the opposite side of the first surface and multiple first penetrating holes, a first conductive portion formed on the first surface of the substrate and made of a first plated cover layer, a second conductive portion formed on the second surface of the substrate and made of a second plated cover layer, the second conductive portion being positioned opposite the first conductive portion, and multiple first through-hole conductors made of conductors formed in the multiple first penetrating holes, respectively, the multiple first through-hole conductors connecting the first conductive portion and the second conductive portion. The first conductive portion, the second conductive portion and the first through-hole conductors form a first through-hole connection section which sets up either a power-source through-hole conductor or a ground through-hole conductor.

### CROSS-REFERENCE TO RELATED APPLICATIONS

The present application claims the benefits of priority to U.S. Application No. 61/238,468, filed Aug. 31, 2009. The contents of that application are incorporated herein by reference in their entirety.

### BACKGROUND OF THE INVENTION

1. Field of the Invention

The present invention relates to a printed wiring board and its manufacturing method.

2. Discussion of the Background

Japanese Laid-Open Patent Publication 2007-88202 describes a printed wiring board having through holes with different widths. Larger-diameter through holes are used for power source or ground, for example; and smaller-diameter through holes are used for signal transmission, for example. The contents of Japanese Patent Application No. 2007-88202 are incorporated herein by reference in their entirety in the present application.

### SUMMARY OF THE INVENTION

According to one aspect of the present invention, a printed wiring board includes a substrate having a first surface and a second surface on the opposite side of the first surface and multiple first penetrating holes, a first conductive portion formed on the first surface of the substrate and made of a first plated cover layer, a second conductive portion formed on the second surface of the substrate and made of a second plated cover layer, the second conductive portion being positioned opposite the first conductive portion, and multiple first through-hole conductors made of conductors formed in the multiple first penetrating holes, respectively, the first through-hole conductors connecting the first conductive portion and the second conductive portion. The first conductive portion, the second conductive portion and the first through-hole conductors form a first through-hole connection section which sets up either a power-source through-hole conductor or a ground through-hole conductor.

According to another aspect of the present invention, a method for manufacturing a printed wiring board includes preparing a substrate having a first surface and a second surface on the opposite side of the first surface, forming multiple first penetrating holes that penetrate through the substrate from the first surface to the second surface, forming multiple first through-hole conductors in the multiple first penetrating holes, respectively, forming a first plated cover layer on the first surface of the substrate such that a first conductive portion connected to the first through-hole conductors is formed, and forming a second plated cover layer on the second surface of the substrate such that a second conductive portion connected to the first through-hole conductors is formed. The first conductive portion, the second conductive portion and the first through-hole conductors form a first through-hole connection section which sets up either a power-source through-hole conductor or a ground through-hole conductor.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a view showing a printed wiring board according to an embodiment of the present invention;

FIG. 2A is a perspective view showing an example of a first through-hole connection section;

FIG. 2B is a plan view of FIG. 2A;

FIG. 3A is a perspective view showing another example of a first through-hole connection section;

FIG. 3B is a plan view of FIG. 3A;

FIG. 4A is a perspective view showing an example of a second through-hole connection section;

FIG. 4B is a plan view of FIG. 4A;

FIG. 5 is a view showing a relationship between positions of first through-hole conductors and directions in which reinforcing materials are arranged;

FIG. 6 is a view showing positions of the connected portions of via conductors on a first conductive portion and a second conductive portion;

FIG. 7 is a graph showing simulation results regarding impedance;

FIG. 8 is a view to illustrate a step for preparing a double-sided copper-clad laminate;

FIG. 9 is a view to illustrate a step for forming a first penetrating hole and a second penetrating hole;

FIG. 10 is a view to illustrate a step for forming electroless plated films;

FIG. 11 is a view to illustrate a step for forming electrolytic plated films;

FIG. 12 is a view to illustrate a step for patterning conductive films on both surfaces of a substrate;

FIG. 13 is a view to illustrate a step for forming an insulation layer on both surfaces of a core substrate;

FIG. 14 is a view to illustrate a step for forming electroless plated films;

FIG. 15 is a view to illustrate a step for forming electrolytic plated films;

FIG. 16 is a view to illustrate a step for etching the electroless plated films;

FIG. 17 is a view to illustrate a step for forming a solder-resist layer;

FIG. 18A is a perspective view showing an example of first through-hole conductors in a straight shape;

FIG. 18B is a perspective view showing another example of first through-hole conductors in a straight shape;

FIG. 19 is a perspective view showing an example of a second through-hole conductor in a straight shape;

FIG. 20 is a view showing an example of a printed wiring board having holes shallower than a first opening or a second opening; and

FIG. 21 is a view showing an example of a printed wiring board where reinforcing material protrudes into a first through-hole conductor and a second through-hole conductor.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction in a wiring board, corresponding to a direction along a normal line (or a direction of the thickness of a core substrate) to the main surfaces (upper and lower surfaces) of the wiring board. On the other hand, arrows (X1, X2) and (Y1, Y2) each indicate a direction perpendicular to a lamination direction (directions parallel to the main surfaces of the wiring board). The main surfaces of a wiring board are on the X-Y plane. Side surfaces of a wiring board are on the X-Z plane or the Y-Z plane.

In the present embodiment, two main surfaces facing opposite lamination directions are referred to as a first surface (a surface on the arrow-Z1 side) and as a second surface (a surface on the arrow-Z2 side). In a lamination direction, the side closer to a core is referred to as a lower layer (or an inner-layer side), and the side farther from the core is referred to as an upper layer (or an outer-layer side). A layer including a conductive pattern that functions as wiring for a circuit or the like is referred to as a wiring layer. The conductor formed in a through hole is referred to as a through-hole conductor. The conductor formed in a via hole and electrically connecting an upper-layer wiring layer and a lower-layer wiring layer to each other is referred to as a via conductor. In addition, “width” indicates a diameter if it is a circle, and indicates √(2×cross section/π) in those other than a circle. If a hole tapers, “widths” in two or more holes may be determined to be the same or not the same by comparing average values or the like.

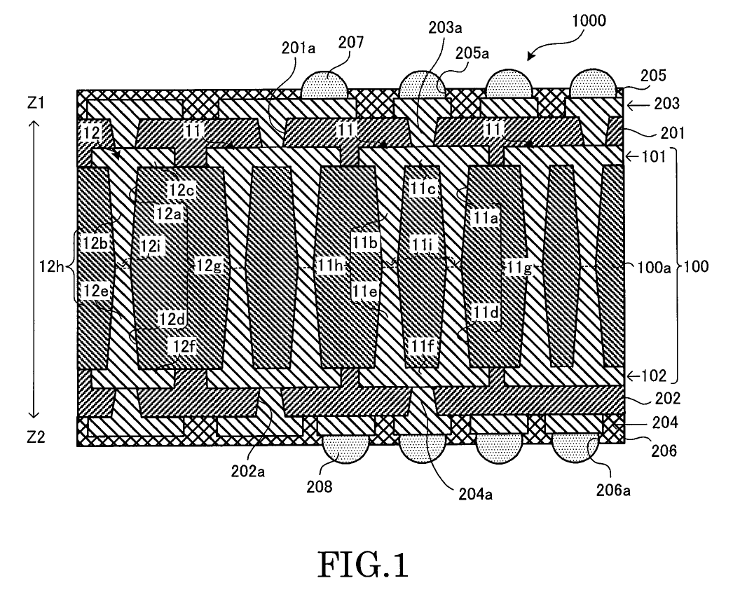

Wiring board 1000 of the present embodiment is a printed wiring board. As shown in FIG. 1, wiring board 1000 has core substrate 100, insulation layers (201, 202), wiring layers (203, 204) made of copper, for example, solder-resist layers (205, 206) and external connection terminals (207, 208) made of solder.

Core substrate 100 has substrate (100a), wiring layers (101, 102) made of copper, for example, first through-hole connection section 11 and second through-hole connection section 12. Wiring layer 101 is formed on a first surface of substrate (100a), and wiring layer 102 is formed on a second surface of substrate (100a). First through-hole connection section 11 is used for power source or ground. Second through-hole connection section 12 is used for signal transmission.

Substrate (100a) has a first surface (a surface on the arrow-Z1 side) and a second surface (a surface on the arrow-Z2 side) opposite the first surface. Substrate (100a) is made of epoxy resin, for example. Epoxy resin is preferred to include reinforcing material, for example, glass fiber (such as glass cloth or glass non-woven fabric) or aramid fiber (such as aramid non-woven fabric), which is impregnated with resin. The material for substrate (100a) is not limited specifically. Reinforcing material is such as that with a smaller thermal expansion coefficient than primary material (epoxy resin in the present embodiment).

First through-hole connection section 11 is formed with first conductive portion (first plated cover layer) (11c), second conductive portion (second plated cover layer) (110 and first through-hole conductor (11h). Second through-hole connection section 12 is formed with third conductive portion (third plated cover layer) (12c), fourth conductive portion (fourth plated cover layer) (121) and second through-hole conductor (12h).

In substrate (100a), first penetrating hole (11g) and second penetrating hole (12g) are formed, penetrating from the first surface toward the second surface. First penetrating hole (11g) and second penetrating hole (12g) are made up of first openings (11a, 12a) tapering from the first surface toward the second surface, and of second openings (11d, 12d) tapering from the second surface toward the first surface. Accordingly, narrowed portions (11i, 12i) (surfaces with the smallest diameter) are formed in areas at half the thickness of substrate (100a). First openings (11a, 12a) and second openings (11d, 12d) have substantially symmetrical shapes with narrowed portions (11i, 12i) at their borders. However, first penetrating hole (11g) and second penetrating hole (12g) are not limited to such, and they may have asymmetrical shapes with narrowed portions (11i, 12i) at their borders. The shape of the openings of first penetrating hole (11g) and second penetrating hole (12g) is circular, for example. However, the shape of those openings is not limited specifically, and it may be polygonal having four sides, six sides or eight sides, for example.

Conductors (11b, 12b) are filled in first openings (11a, 12a), and conductors (11e, 12e) are filled in second openings (11d, 12d). Accordingly, first through-hole conductor (11h) is formed in first penetrating hole (11g), and second through-hole conductor (12h) is formed in second penetrating hole (12g). First through-hole conductor (11h) and second through-hole conductor (12h) are preferred to be made of copper plating.

First conductive portion (11c) is formed on the first surface of substrate (100a), and second conductive portion (11f) is formed on the second surface of substrate (100a). Second conductive portion (11f) is positioned opposite first conductive portion (11c).

Third conductive portion (12c) is formed on the first surface of substrate (100a), and fourth conductive portion (121) is formed on the second surface of substrate (100a). Fourth conductive portion (12f) is positioned opposite third conductive portion (12c).

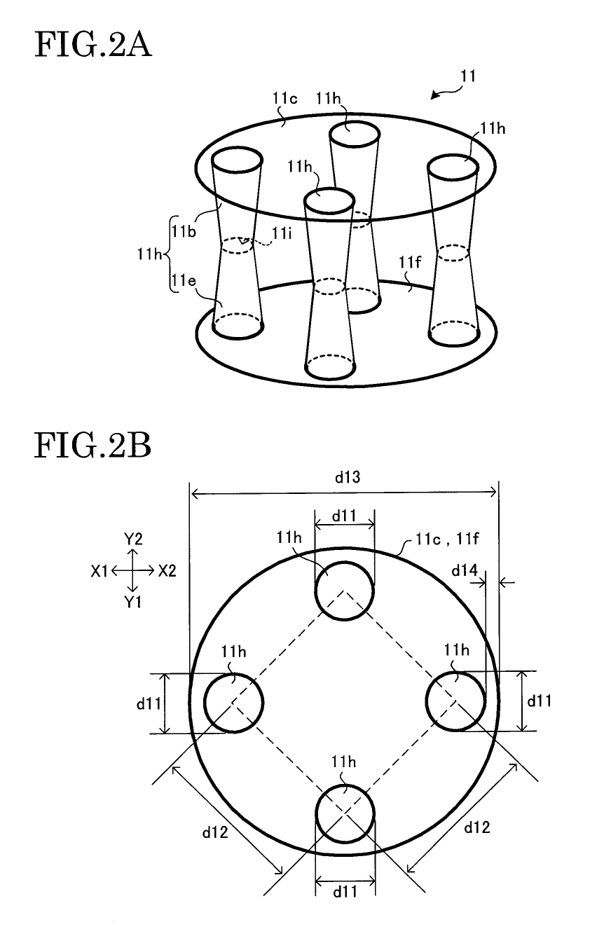

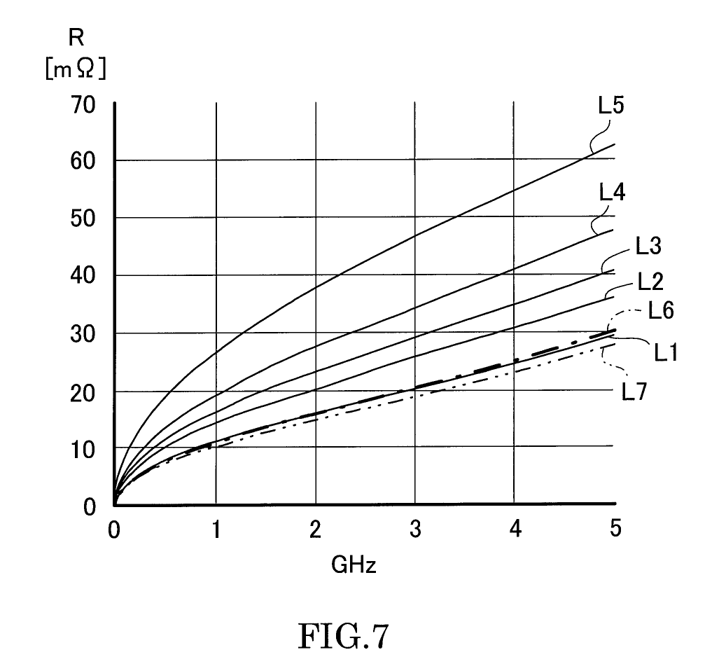

As shown in FIG. 2A and FIG. 2B (a plan view of FIG. 2A), first through-hole connection section 11 is formed with first conductive portion (11c), second conductive portion (11f) and four through-hole conductors (11h) shaped like a Japanese hand drum (a shape similar to that of an hourglass). First conductive portion (11c) and second conductive portion (11f) are connected to each other by four first through-hole conductors (11h). By bundling multiple first through-hole conductors (11h) and connecting them commonly to first conductive portion (11c) and second conductive portion (11f), impedance may be decreased (see FIG. 7). Also, since first conductive portion (11c) and second conductive portion (11f) are connected by means of multiple first through-hole conductors (11h), even if one of the first through-hole conductors (11h) ruptures, first conductive portion (11c) and second conductive portion (11f) will not be completely disconnected. As a result, electrical connection malfunctions between first conductive portion (11c) and second conductive portion (11f) will be suppressed.

In the present embodiment, four first through-hole conductors (11h) are arranged to be positioned in a quadrangle. Pitches (d12) of adjacent first through-hole conductors (11h) are substantially the same. Accordingly, four first through-hole conductors (11h) are arranged as a square, being positioned as point symmetrical. By arranging first through-hole conductors (11h) to be a regular polygon, widths may be reduced in first conductive portion (11c) and second conductive portion (11f). Regarding first penetrating hole (11g) (first through-hole conductor (11h)), the maximum width (d11) is 90 μm, for example, and the minimum width (width of narrowed portion (11i)) is 60 μm, for example. Pitch (d12) of adjacent first through-hole conductors (11h) is 225 μm, for example. Width (d13) of first conductive portion (11c) and second conductive portion (11f) is 508 μm, for example. Also, regarding the positions of first through-hole conductors (11h), distance (d14) from the edges of first conductive portion (11c) and second conductive portion (11f) is 50 μm, for example. However, such measurements are not limited to any specific values.

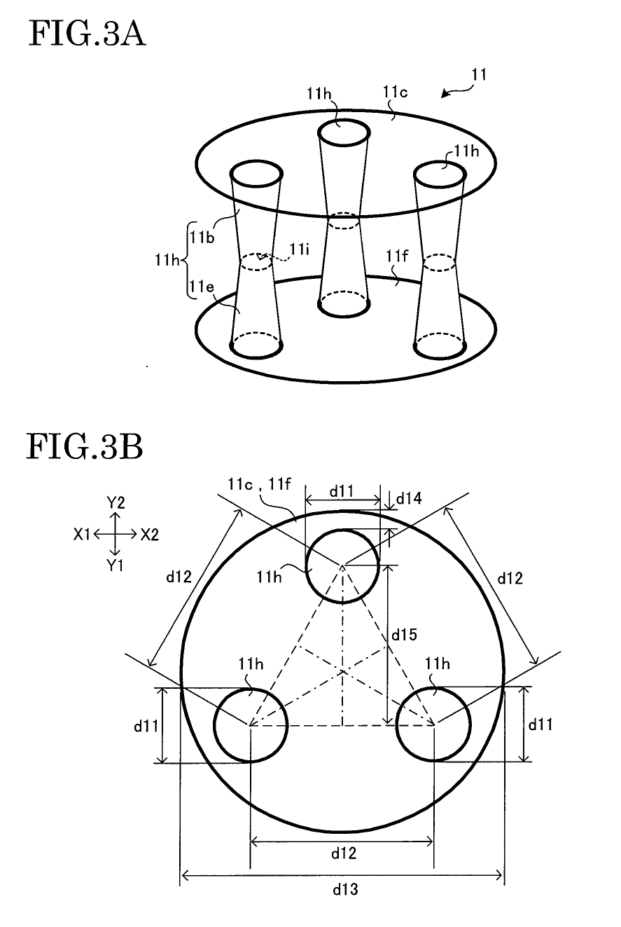

The positioning of first through-hole conductors (11h) is not limited to being quadrangular, and any other shape may be employed. For example, as shown in FIG. 3A and FIG. 3B (plan view of FIG. 3A), three first through-hole conductors (11h) may be positioned as a triangle. In such a case, regarding first penetrating hole (11g) (first through-hole conductor (11h)), width (d11) is 90 μm, for example, and the minimum width (width of narrowed portion (11i)) is 60 μm, for example. Pitch (d12) of adjacent first through-hole conductors (11h) is 225 μm, for example. Widths (d13) of first conductive portion (11c) and second conductive portion (11f) are 449.8 μm, for example. Regarding the positions of first through-hole conductors (11h), distance (d14) from the edges of first conductive portion (11c) and second conductive portion (11f) is 50 μm, for example, and distance (d15) between two first through-hole conductors (11h) and one first through-hole conductor (11h) is 194.85 μm, for example.

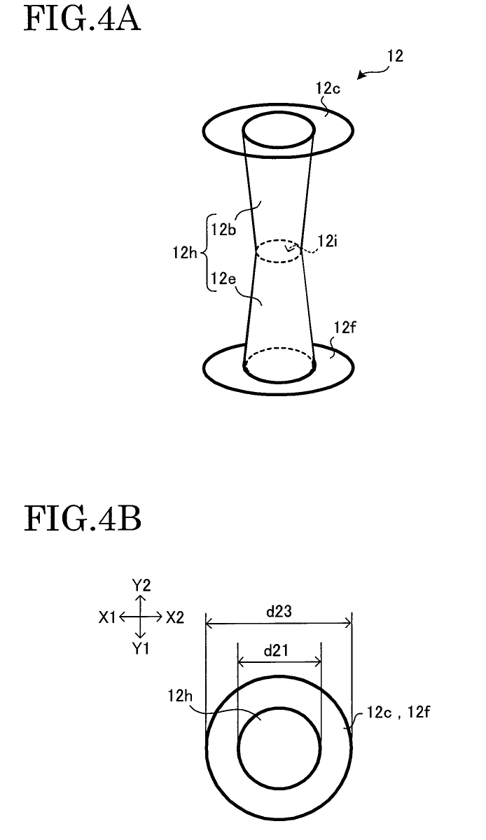

As shown in FIG. 4A and FIG. 4B (plan view of FIG. 4A), second through-hole connection section 12 is formed with third conductive portion (12c), fourth conductive portion (12f) and one second through-hole conductor (12h) shaped like the hand drum. Third conductive portion (12c) and fourth conductive portion (12f) are connected to each other by one second through-hole conductor (12h).

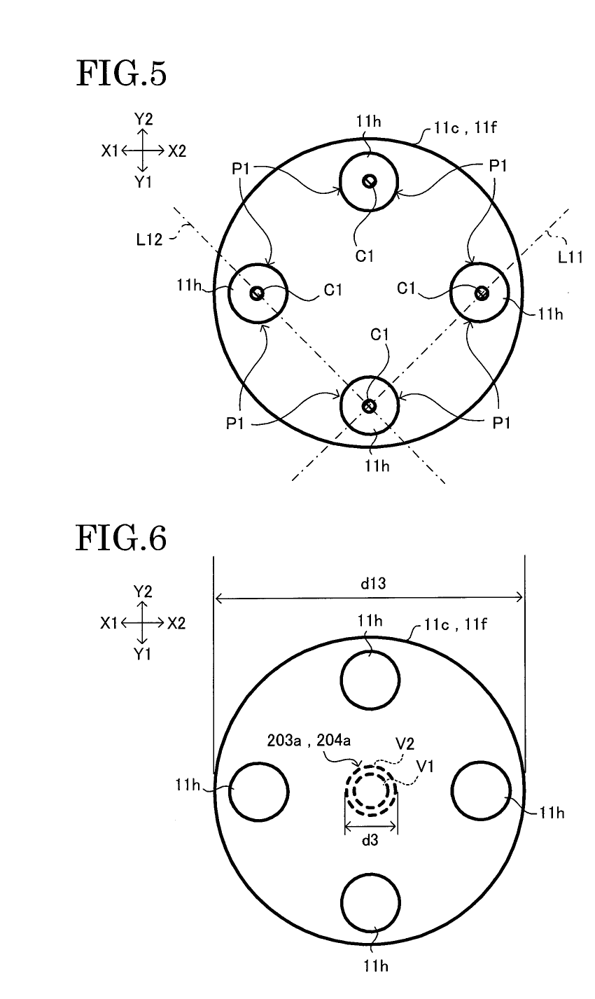

When first through-hole conductors (11h) are positioned as shown in FIG. 5, for example, the reinforcing materials in substrate (100a) are preferred to be arranged in two directions perpendicular to each other (each 45 degrees diagonal to directions X and Y). In such a case, when a pair (P1) of first through-hole conductors (11h), positioned in the shortest distance among first through-hole conductors (11h), is viewed on a plane, virtual center lines (L11, L12), which connect centers (C1) of first through-hole conductors (11h), are substantially parallel to the directions in which reinforcing materials are arranged. Accordingly, the pair (P1) of first through-hole conductors (11h) will tend to be electrically connected to each other through the conductor squeezed from first through-hole conductors (11h) into the reinforcing material. Then, when the pair (P1) of first through-hole conductors (11h) becomes electrically connected to each other, it is thought that such first through-hole conductors (11h) may be considered to be one through-hole conductor. As a result, it is believed that mutual inductance will be suppressed and loop inductance will decrease. Also, by driving argon, for example, to intentionally cause a flaw at a predetermined spot of substrate (100a), the conductor in first through-hole conductor (11h) may be squeezed into substrate (100a).

Width (d11) (FIG. 2B) of first penetrating hole (11g) and width (d21) (FIG. 4B) of second penetrating hole (12g) are substantially the same. Accordingly, for example, when performing electrolytic plating by brush plating, the circulation efficiency increases of the plating solution into first penetrating hole (11g) and second penetrating hole (12g), thus facilitating setting the conditions. In addition, performance improves when filling first penetrating hole (11g) and second penetrating hole (12g), leading to an improvement in flatness features of the surface of first conductive portion (11c) and the surface of second conductive portion (11f). Width (d11) and width (d21) have maximum/minimum=90 μm/60 μm, for example.

First conductive portion (11c) and second conductive portion (11f) have the same width (d13) as each other. Also, third conductive portion (12c) and fourth conductive portion (12f) have the same width (d23) as each other.

Insulation layer 201 is formed on the first surface of core substrate 100, and insulation layer 202 is formed on the second surface of core substrate 100. Insulation layers (201, 202) work as interlayer insulation layers. Insulation layers (201, 202) are made of cured prepreg, for example. As for such a prepreg, for example, the following is used: base materials such as glass fiber or aramid fiber are impregnated with resins such as epoxy resin, polyester resin, bismaleimide triazine resin (BT resin), imide resin (polyimide), phenol resin, or allyl polyphenylene ether resin (A-PPE resin). However, instead of prepreg, liquid or film-type thermosetting resins or thermoplastic resins, composites of such resins, or even RCF (resin-coated copper foil) may also be used.

Via hole (201a) is formed in insulation layer 201, and via hole (202a) is formed in insulation layer 202. By filling conductor in via holes (201a, 202a), via conductors (203a, 204a) are formed. Wiring layer 203 is formed on insulation layer 201, and wiring layer 204 is formed on insulation layer 202. Via conductor (203a) is connected to first conductive portion (11c) and third conductive portion (12c), and via conductor (204a) is connected to second conductive portion (11f) and fourth conductive portion (12f). Accordingly, wiring layer 203 and wiring layer 101 (first conductive portion (11c)) are connected by via conductor (203a). Also, wiring layer 204 and wiring layer 102 (second conductive portion (11f)) are connected by via conductor (204a).

As shown in FIG. 6, connected portions (V1) of via conductors (203a, 204a) are preferred to be set in areas which are not in contact with first through-hole conductors (11h). In such a structure, via conductors (203a, 204a) are formed in areas away from the connected spots of through-hole conductors (11h), compared with cases in which via conductors (203a, 204a) are formed directly on first through-hole conductors (11h). Thus, tensile forces in directions Z generated from thermal expansion or the like in substrate (100a) will seldom be conveyed to via conductors (203a, 204a). As a result, connection reliability will improve in via conductors (203a, 204a). Width (d13) of first conductive portion (11c) and second conductive portion (11f) is preferred to be 5-10 times as wide as width (d3) of conductive portions (V2) of the via conductors. Within such a range, excellent electrical characteristics are achieved.

In the present embodiment, via conductors (203a, 204a) are each filled vias. However, via conductors (203a, 204a) are not limited to such, and they may be conformal vias where the conductor is formed on wall surfaces of via holes (201a, 202a).

Wiring layer 203 and solder-resist layer 205 are formed on the first surface of insulation layer 201, and wiring layer 204 and solder-resist layer 206 are formed on the second surface of insulation layer 202. Solder-resist layers (205, 206) are each made of resin, for example, a photosensitive resin using acrylic-epoxy resin, a thermosetting resin mainly containing epoxy resin, a UV-setting resin, or the like.

In solder-resist layer 205, opening (205a) exposing part of wiring layer 203 is formed. Also, in solder-resist layer 206, opening (206a) exposing part of wiring layer 204 is formed. External connection terminal 207 is formed in opening (205a), and external connection terminal 208 is formed in opening (206a). External connection terminals (207, 208) are used for electrical connection with other wiring boards and electronic components, for example. Wiring board 1000 may be used as a circuit board for cell phones or the like by being mounted on other wiring boards using one or both of its surfaces. Electronic components such as an IC or the like are mounted on wiring board 1000 according to requirements.

Next, characteristics of wiring board 1000 are described. Simulations on wiring board 1000 and comparative examples were carried out. Such simulations were conducted on samples #1-#7.

Samples #1-#4 are each a single through-hole conductor with a straight shape. Further, samples #1-#4 are each a through-hole conductor formed by filling resin in a penetrating hole.

Sample #1 is set as follows: core thickness 400 μm, through-hole diameter 250 μm, conductive-portion diameter 400 μm, through-hole pitch 550 μm, L (line)/S (space)=75 μm/75 μm. Sample #2 is set as follows: core thickness 400 μm, through-hole diameter 180 μm, conductive-portion diameter 330 μm, through-hole pitch 480 μm, L/S=75 μm/75 μm. Sample #3 is set as follows: core thickness 400 μm, through-hole diameter 150 μm, conductive-portion diameter 300 μm, through-hole pitch 450 μm, L/S=75 μm/75 μm. Sample #4 is set as follows: core thickness 400 μm, through-hole diameter 120 μm, conductive-portion diameter 270 μm, through-hole pitch 420 μm, L/S=75 μm/75 μm.

Sample #5 is a single Japanese hand-drum-shaped through-hole conductor formed by filling conductor (copper plating) in a penetrating hole. Sample #5 is set as follows: core thickness 400 μm, through-hole diameter (maximum/minimum)=90 μm/60 μm, conductive-portion diameter 140 μM, through-hole pitch 290 μm, L/S=75 μm/75 μm.

Sample #6 is first conductive section 11 of wiring board 1000; namely, sample #6 is formed with four hand-drum-shaped through-hole conductors (positioned as a square as shown in FIG. 2A). Sample #6 is set as follows: core thickness 400 μm, through-hole diameter (maximum/minimum)=90 μm/60 μm, conductive-portion diameter 508 μm, conductive-portion pitch 658 μm, L/S=75 μm/75 μm.

In sample #7, four straight-shaped through-hole conductors are positioned the same as in sample #6. Such through-hole conductors are formed by filling conductor (copper plating) in penetrating holes. Sample #7 is set as follows: core thickness 400 μm, through-hole diameter 90 μm, conductive-portion diameter 508 μm, conductive-portion pitch 658 μm, L/S=75 μm/75 μm.

FIG. 7 shows the simulation results. In the graph, curved lines (L1, L2, L3, L4, L5, L6, L7) show the impedance of samples #1, #2, #3, #4, #5, #6 and #7. As shown in the graph, the relationships of the impedance in samples #1-#7 were #7≈#6≈#1<#2<#3<#4<#5. Namely, in samples #6 and #7 related to the present embodiment, substantially the same impedance was obtained as in sample #1 with a through-hole diameter of 250 μm. From such results, by bundling multiple first through-hole conductors (11h) and connecting them commonly to first conductive portion (11c) and second conductive portion (11f), it is thought that the impedance may be decreased. Without being bound by theory, the reason for this is assumed as follows: Since the impedance between conductive portions is affected by the total value of cross sections of through-hole conductors connecting such conductive portions (hereinafter referred to as the cross section between conductive portions), the cross section between conductive portions increases when multiple through-hole conductors are used to connect the conductive portions, compared with cases where one through-hole conductor is used to connect the conductive portions.

Wiring layers (101, 102) in wiring board 1000 are manufactured by a tenting method, for example. However, such a case is only an example, and the manufacturing method for wiring board 1000 is not limited to a tenting method.

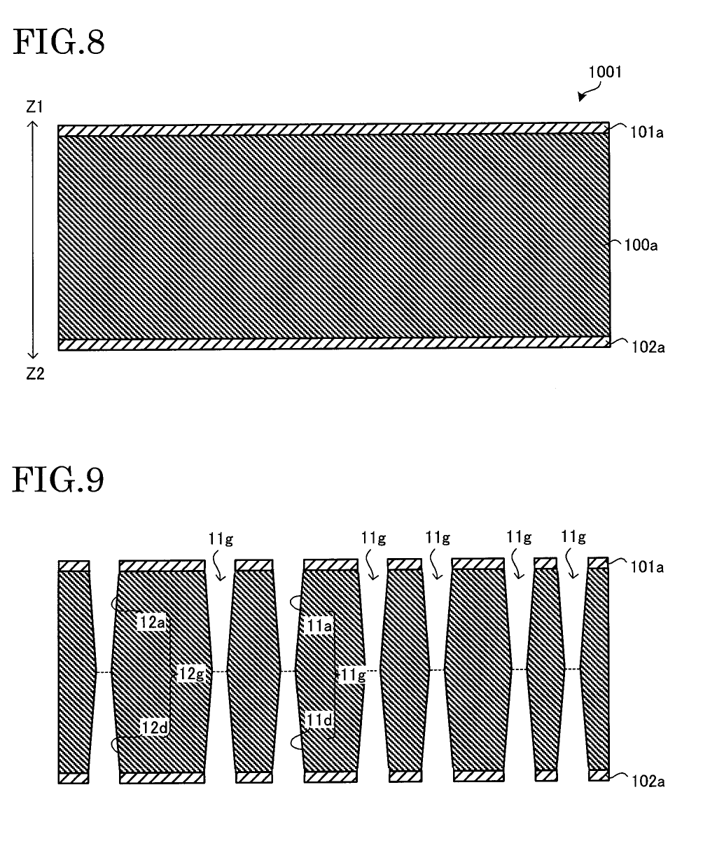

First, as shown in FIG. 8, double-sided copper-clad laminate 1001 is prepared. Double-sided copper-clad laminate 1001 is formed with substrate (100a) and copper foils (101a, 102a). Copper foil (101a) is formed on the first surface of substrate (100a), and copper foil (102a) is formed on the second surface of substrate (100a). Double-sided copper-clad laminate 1001 is preferred to have alignment marks in its four corners, for example.

Next, based on the alignment marks, for example, a CO₂ laser or a UV laser is irradiated on the first and second surfaces of double-sided copper-clad laminate 1001. For example, a laser whose central energy is higher than its peripheral energy is irradiated. Alternatively, a multi-pulse laser may also be irradiated. In such a case, laser diameters are preferred to be set gradually smaller from the first pulse toward the final pulse. Also, for the final pulse, a laser may be used whose energy density is higher in the center than in the periphery. The number of laser irradiations is not limited specifically. Laser irradiation may be performed on one surface at a time, or on both surfaces simultaneously.

By doing so, as shown in FIG. 9, first penetrating hole (11g) and second penetrating hole (12g) are formed, penetrating copper foils (101a, 102a). First penetrating hole (11g) and second penetrating hole (12g) are preferred to be positioned in such a way that when pairs (P1) of first through-hole conductors (11h) are viewed on a plane, virtual center lines (L11, L12) connecting centers (C1) of first through-hole conductors (11h) will be parallel to the directions in which reinforcing materials are arranged (see FIG. 5). First penetrating hole (11g) and second penetrating hole (12g) are made up of first openings (11a, 12a) tapering from the first surface toward the second surface, and of second openings (11d, 12d) tapering from the second surface toward the first surface. Width (d11) of first penetrating hole (11g) (FIG. 2B) and width (d21) of second penetrating hole (12g) (FIG. 4B) are made substantially the same. Then, desmearing is conducted. After that, according to requirements, surface improvement through plasma treatment, corona treatment or the like may be conducted on the wall surfaces or the like of first penetrating hole (11g) and second penetrating hole (12g).

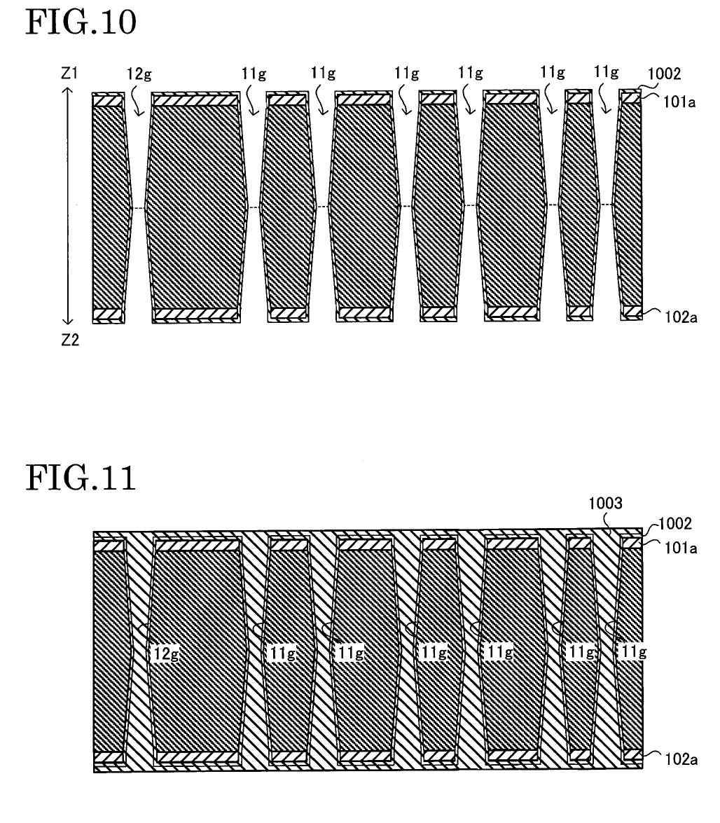

Next, as shown in FIG. 10, a Pd catalyst or the like, is provided, for example, and then electroless plating is performed on the substrate surfaces including the wall surfaces of first penetrating hole (11g) and second penetrating hole (12g) to form electroless plated film 1002, for example. Electroless plated film 1002 is made of copper, for example. However, the material for electroless plated film 1002 is not limited to copper, and nickel, titanium, chrome and others may also be employed. Other than electroless plated film, sputtered film and CVD film may also be used. In the case of sputtered film and CVD film, a catalyst is not required.

Next, as shown in FIG. 11, electrolytic plating is performed to form electrolytic plated film 1003 by using electroless plated film 1002 as a seed layer. Electrolytic plated film 1003 is made of copper, for example. However, the material for electrolytic plated film 1003 is not limited to copper, and nickel, solder and others may also be employed.

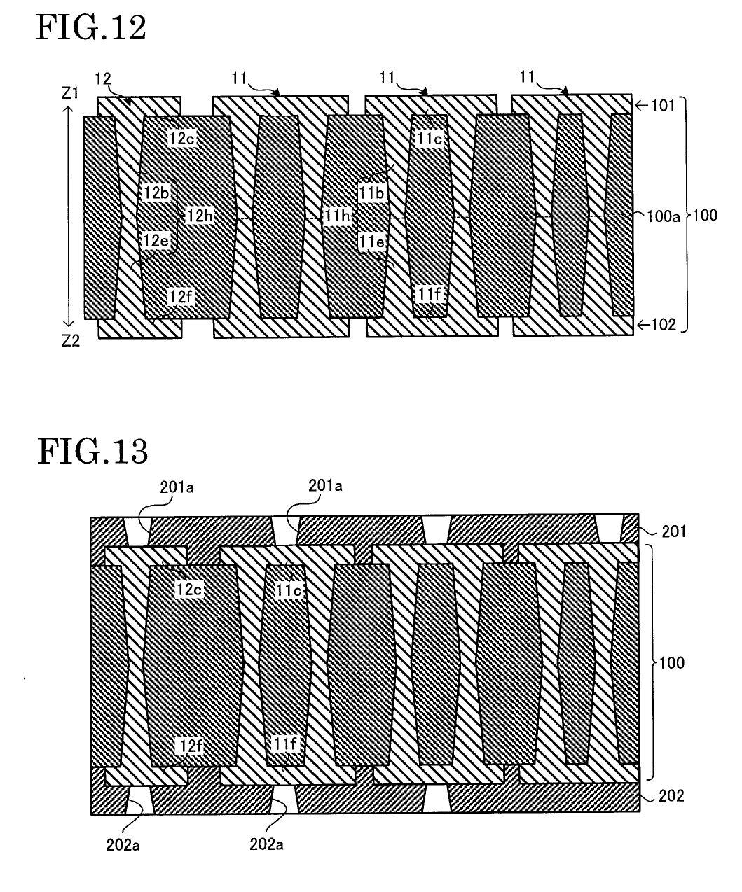

Next, as shown in FIG. 12, the conductive films on both surfaces of substrate (100a) are patterned by photolithographic technology. By doing so, core substrate 100 is formed having wiring layers (101, 102), first through-hole connection section 11 and second through-hole connection section 12. In the present embodiment, first through-hole conductor (11h) and second through-hole conductor (12h) are filled in first penetrating hole (11g) and second penetrating hole (12g) through plating (see FIG. 11). First conductive portion (11c) and second conductive portion (11f) are positioned opposite each other. Also, third conductive portion (12c) and fourth conductive portion (12f) are positioned opposite each other.

After that, according to requirements, by etching for example, the surfaces of wiring layers (101, 102) are roughened. By doing so, adhesiveness is ensured with insulation layers (201, 202), which are to be arranged as their respective upper layers.

Next, as shown in FIG. 13, insulation layer 201 is formed on the first surface of core substrate 100 and insulation layer 202 is formed on the second surface of core substrate 100. Then, by a laser, for example, via hole (201a) is formed in insulation layer 201 and via hole (202a) is formed in insulation layer 202. After that, according to requirements, the surfaces of insulation layers (201, 202) are roughened by etching, for example.

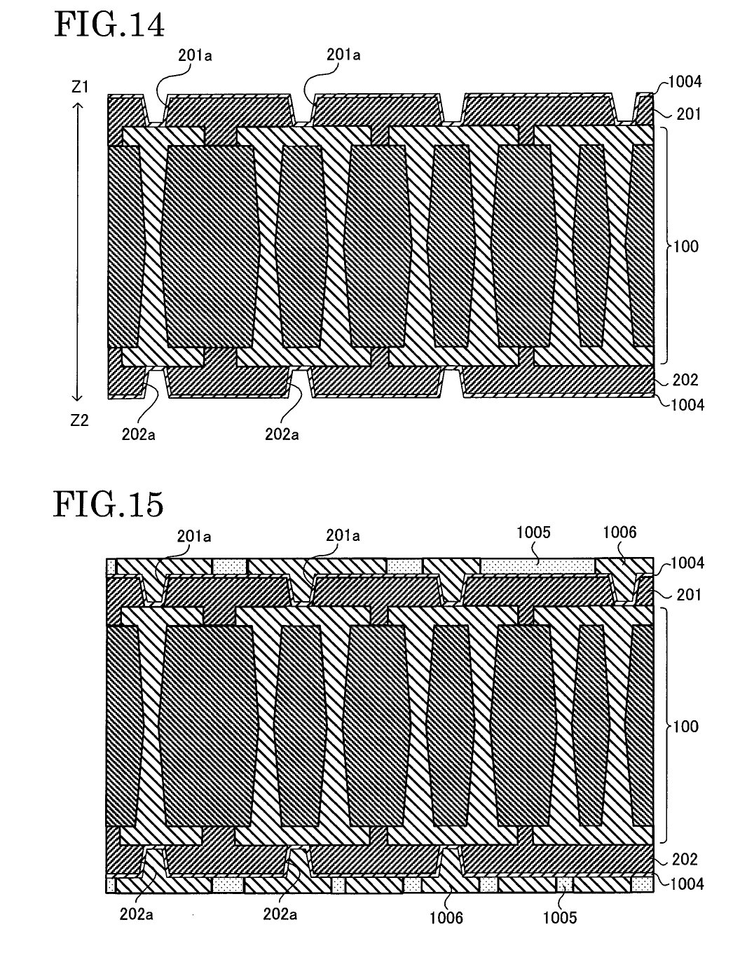

Next, as shown in FIG. 14, electroless plated film 1004 is formed by electroless copper plating, for example. Then, by arranging dry film and patterning it, as shown in FIG. 15, for example, plating resist 1005 is formed on electroless plated film 1004. Then, by electrolytic copper plating, for example, electrolytic plated film 1006 is formed in opening portions of plating resist 1005.

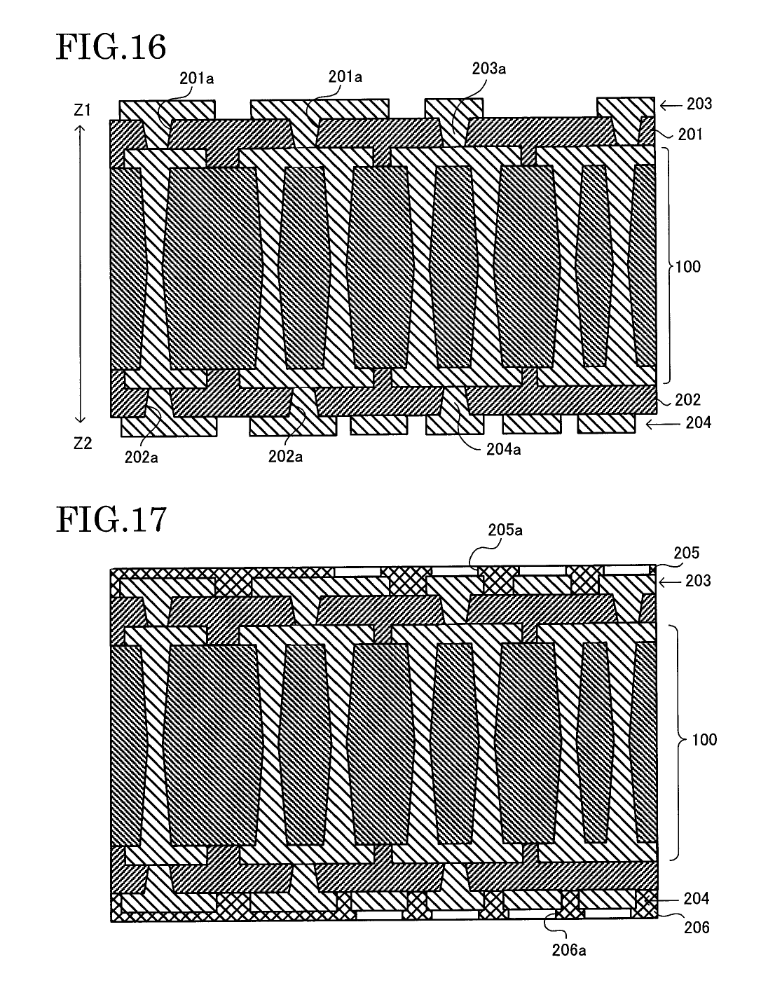

Next, as shown in FIG. 16, for example, plating resist 1005 is removed using a resist-removing solution containing amine, solvent, strong alkali and water. Then, electroless plated film 1004 is etched (quick etching). By doing so, wiring layers (203, 204) and via conductors (203a, 204a) are formed. Via conductor (203a) is connected to first conductive portion (11c) and third conductive portion (12c), and via conductor (204a) is connected to second conductive portion (11f) and fourth conductive portion (12f). According to requirements, connected portions (V1) of via conductors (203a, 204a) are arranged in areas which are not in contact with first through-hole conductors (11h) (see FIG. 6).

After that, as shown in FIG. 17, for example, solder-resist layers (205, 206) are formed by application or lamination, and openings (205a, 206a) are formed in solder-resist layers (205, 206) by a photolithographic technique, for example. Then, after printing solder paste or mounting solder balls in openings (205a, 206a), and conducting a reflow, external connection terminals (207, 208) (solder bumps) are formed in openings (205a, 206a). Accordingly, wiring board 1000 is completed (FIG. 1).

In the present embodiment, first through-hole conductor (11h) and second through-hole conductor (12h) are formed by filling conductor (such as copper) in first penetrating hole (11g) and second penetrating hole (12g) through plating. Thus, steps for filling resin and for polishing are not required. As a result, simplified procedures and reduced costs may be achieved.

Wiring board 1000 is a double-sided printed wiring board having wiring layers (203, 204) on the upper and lower surfaces of a core. However, wiring boards which can be manufactured by the present invention are not limited to such. For example, the manufacturing method according to the present invention may be applied for manufacturing a single-sided printed wiring board having a wiring layer only on either the upper or lower surface of a core.

So far, a printed wiring board and its manufacturing method according to an embodiment of the present invention have been described. However, the present invention is not limited to the above embodiment, and may be carried out by modifying as follows, for example.

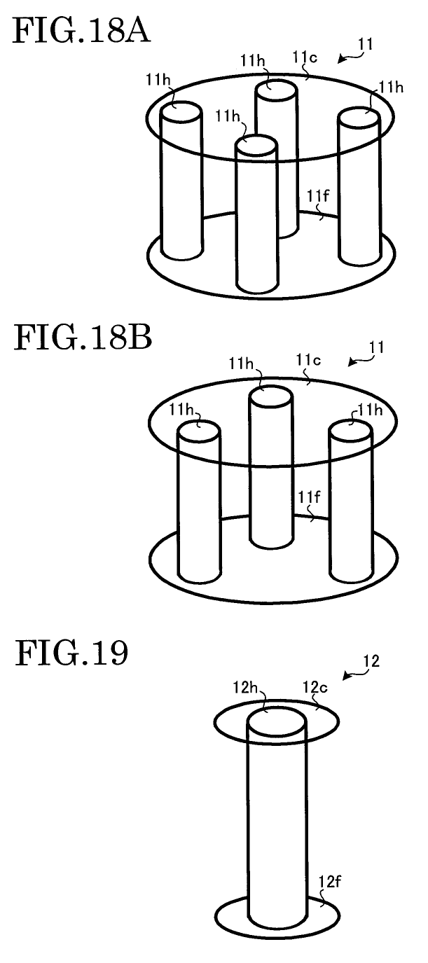

The shape of first through-hole conductor (11h) is not limited to that of the hand drum shown in FIG. 2A and FIG. 3A as examples. As shown in FIGS. 18A and 18B, the shape may be straight, for example. Also, the shape of second through-hole conductor (12h) is not limited to that of the hand drum shown in FIG. 4A as an example. As shown in FIG. 19, it may be straight, for example. Furthermore, when multiple through-hole conductors are used to connect conductive portions, hand-drum and straight shapes may be mixed.

In the above embodiment, through-hole conductors (11h, 12h) are formed by filling conductor in first penetrating hole (11g) and second penetrating hole (12g). However, through-hole conductors (11h, 12h) may be formed on the inner walls of first penetrating hole (11g) and second penetrating hole (12g) without filling a conductor. In such a case, resin or the like will be filled in first penetrating hole (11g) and second penetrating hole (12g) (on the inner side of through-hole conductors (11h, 12h)).

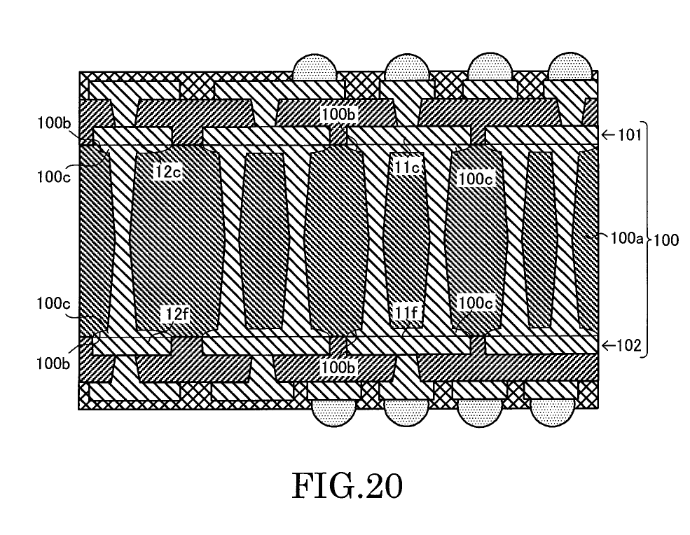

As shown in FIG. 20, holes (100b) shallower than first opening (11a) and second opening (11d) may be formed underneath first conductive portion (11c) and second conductive portion (11f), and then may be filled with conductor (100c) made of copper or the like. In such a structure, practically, the thicknesses of first conductive portion (11c) and second conductive portion (12c) increase. Thus, electrical characteristics will improve. Such shallow hole (100b) may be formed by a laser, for example. Also, conductor (100c) may be formed by plating, for example.

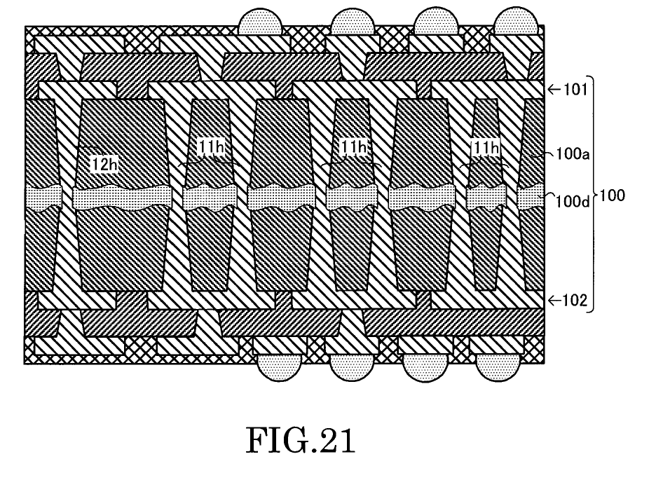

As shown in FIG. 21, reinforcing material (100d) in substrate (100a) may be made to protrude into first through-hole conductor (11h) and second through-hole conductor (12h). By doing so, tensile forces in directions Z may be mitigated in first through-hole conductor (11h) and second through-hole conductor (12h).

A printed wiring board according to one aspect of the present invention is formed with the following: a substrate with a first surface and a second surface opposite the first surface, and having two or more first penetrating holes; a first conductive portion formed on the first surface of the substrate; and a second conductive portion formed on the second surface of the substrate and positioned opposite the first conductive portion. In such a printed wiring board, the first conductive portion and the second conductive portion are connected by two or more first through-hole conductors, and the first through-hole conductors are power-source or ground through-hole conductors.

A method for manufacturing a printed wiring board according to another aspect of the present invention is as follows: preparing a substrate having a first surface and a second surface opposite the first surface; forming two or more first penetrating holes that penetrate from either the first surface or the second surface to the other surface; forming a first through-hole conductor for power-source or ground in the first penetrating holes; and on the first surface and the second surface of the substrate, forming a first conductive portion and a second conductive portion that are connected by the first through-hole conductors. In such a manufacturing method, the first conductive portion and the second conductive portion are connected by two or more first through-hole conductors.

In the above embodiment, the material and size of each layer, and the number of layers may be modified freely.

The order of the steps in the above embodiment may be modified within a scope that does not deviate from the gist of the present invention. Also, some steps may be omitted according to usage requirements or the like. For example, conductive patterns such as first conductive portion (11c) and second conductive portion (11f) may be formed by a semi-additive method or a subtractive method or by any other method.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a substrate having a first surface and a second surface on an opposite side of the first surface, the substrate having a plurality of first penetrating holes;
a first conductive portion formed on the first surface of the substrate and comprising a first plated cover layer;
a second conductive portion formed on the second surface of the substrate and comprising a second plated cover layer, the second conductive portion being positioned opposite the first conductive portion; and
a plurality of first through-hole conductors comprising conductors formed in the plurality of first penetrating holes, respectively, the plurality of first through-hole conductors connecting the first conductive portion and the second conductive portion,
wherein the first conductive portion, the second conductive portion and the plurality of first through-hole conductors form a first through-hole connection section which is configured to set up one of a power-source through-hole conductor and a ground through-hole conductor.

2. The printed wiring board according to claim 1, further comprising:
a third conductive portion formed on the first surface of the substrate,
a fourth conductive portion formed on the second surface of the substrate and positioned opposite the third conductive portion; and
a second through-hole conductor connecting the third conductive portion and the fourth conductive portion,
wherein the substrate has a second penetrating hole, the second through-hole conductor comprises a conductor formed in the second penetrating hole, and the third conductive portion, the fourth conductive portion and the second through-hole conductor form a second through-hole connection section which is configured to set up a signal through-hole conductor.

3. The printed wiring board according to claim 2, wherein the first penetrating holes have a width which is substantially a same as a width of the second penetrating hole.

4. The printed wiring board according to claim 1, wherein each of the first penetrating holes is made up of a first opening and a second opening, the first opening is tapering from the first surface toward the second surface, and the second opening is tapering from the second surface toward the first surface.

5. The printed wiring board according to claim 1, wherein the substrate comprises a resin and a reinforcing material, the reinforcing material is positioned to extend in a direction which is substantially parallel to a center line connecting centers of a pair of the first through-hole conductors positioned in a shortest distance.

6. The printed wiring board according to claim 2, wherein the substrate is made of a resin and a reinforcing material, and the reinforcing material is made to protrude into at least one of the plurality of first through-hole conductors and the second through-hole conductor.

7. The printed wiring board according to claim 2, wherein the plurality of first through-hole conductors and the second through-hole conductor comprise copper plating.

8. The printed wiring board according to claim 1, wherein the first through-hole conductors are positioned from each other at substantially same pitches.

9. The printed wiring board according to claim 1, further comprising:
an insulating layer formed on one of the first conductive portion and the second conductive portion; and
a via conductor formed in the insulating layer and connected to the one of the first conductive portion and the second conductive portion,
wherein the via conductor is connected to a portion of the one of the first conductive portion and the second conductive portion, in which the first through-hole conductors do not make contact to the one of the first conductive portion and the second conductive portion.

10. The printed wiring board according to claim 9, wherein the first conductive portion and the second conductive portion have widths which are 5-10 times as wide as a width of a conductive portion of the via conductor.

11. A method for manufacturing a printed wiring board, comprising:
preparing a substrate having a first surface and a second surface on an opposite side of the first surface;
forming a plurality of first penetrating holes that penetrate through the substrate from the first surface to the second surface;
forming a plurality of first through-hole conductors in the plurality of first penetrating holes, respectively;
forming a first plated cover layer on the first surface of the substrate such that a first conductive portion connected to the first through-hole conductors is formed; and
forming a second plated cover layer on the second surface of the substrate such that a second conductive portion connected to the first through-hole conductors is formed,
wherein the first conductive portion, the second conductive portion and the plurality of first through-hole conductors form a first through-hole connection section which is configured to set up one of a power-source through-hole conductor and a ground through-hole conductor.

12. The method for manufacturing a printed wiring board according to claim 11, further comprising:
forming a second penetrating hole that penetrates through the substrate from the first surface to the second surface;
forming a second through-hole conductor in the second penetrating hole;
forming a third plated cover layer on the first surface of the substrate such that a third conductive portion connected to the second through-hole conductor is formed; and
forming a fourth plated cover layer on the second surface of the substrate such that a fourth conductive portion connected by the second through-hole conductor,
wherein the third conductive portion, the fourth conductive portion and the second through-hole conductor form a second through-hole connection section which is configured to set up a signal through-hole conductor.

13. The method for manufacturing a printed wiring board according to claim 12, wherein the first penetrating holes have a width which is substantially a same as a width of the second penetrating hole.

14. The method for manufacturing a printed wiring board according to claim 11, wherein the forming of the first penetrating holes comprises forming first openings tapering from the first surface toward the second surface and forming second openings tapering from the second surface toward the first surface.

15. The method for manufacturing a printed wiring board according to claim 11, wherein the forming of the first through-hole conductors comprises filling conductors in the first penetrating holes through plating.

16. The method for manufacturing a printed wiring board according to claim 11, further comprising:
forming an insulating layer on one of the first conductive portion and the second conductive portion;
forming a via conductor in the insulating layer such that the via conductor is connected to a portion of the one of the first conductive portion and the second conductive portion, in which the first through-hole conductors do not make contact to the one of the first conductive portion and the second conductive portion.
